(19) United States
(12) Patent Application Publication
(10) Pub. No.: US 2024/0365580 A1
(43) Pub. Date: Oct. 31, 2024

(54) DISPLAY DEVICE AND METHOD FOR MANUFACTURING DISPLAY DEVICE

(71) Applicant: Japan Display Inc., Tokyo (JP)

(72) Inventor: Asami SAKAMOTO, Tokyo (JP)

(21) Appl. No.: 18/641,672

(22) Filed: Apr. 22, 2024

(30) Foreign Application Priority Data
Apr. 27, 2023 (JP) 2023-073201

(51) Int. Cl. H10K 50/17; H10K 59/12; H10K 59/122; H10K 59/35; H10K 102/00

(52) U.S. Cl. CPC H10K 50/17; H10K 59/1201; H10K 59/122; H10K 59/352; H10K 2102/351

(57) ABSTRACT

A display device includes a first pixel electrode, a bank that is provided on the first pixel electrode and partitions between a sub light emitting area and a main light emitting area, a sub hole injection layer that is provided on the first pixel electrode and constitutes the sub light emitting area, a main hole injection layer that is provided on the first pixel electrode and constitutes the main light emitting area, a hole transport layer that is provided on the sub hole injection layer and the main hole injection layer, a light emitting layer, an electron transport layer, and a counter electrode, wherein a concentration of a dopant included in the main hole injection layer is lower than a concentration of a dopant included in the sub hole injection layer.

### CROSS-REFERENCE TO RELATED APPLICATION

The present application claims priority from Japanese application JP2023-073201 filed on Apr. 27, 2023, the content of which is hereby incorporated by reference into this application.

### BACKGROUND OF THE INVENTION

### 1. Field of the Invention

The present invention relates to a display device and a method for manufacturing the display device.

### 2. Description of the Related Art

An organic electroluminescence (EL) display using an organic EL material as a light emitting element (organic EL element) of a display unit has been known. In some cases, some of holes injected from an anode may leak in an unintended direction in an organic EL display device light emitting device, resulting in mixture of colors. JP2016-219125A describes solving this problem by cutting or increasing the resistance of the charge injection and transport layer.

In a display device that emits red, green, and blue light, the driving voltage of blue light emission is higher than that of red light emission and green light emission. As such, when blue light is emitted, red light and green light may be unintentionally emitted due to leakage of holes. This generates mixture of light colors. Preferably, the driving voltage of the red light emission and the green light emission may be increased so as to inhibit such unintended light emission, but power consumption increases.

### SUMMARY OF THE INVENTION

One or more embodiments of the present invention have been conceived in view of the above, and an object thereof is to provide a display device and a method for manufacturing the display device capable of inhibiting unintentional light emission while reducing the power consumption.

### Solution to Problem

A display device according to an aspect of the present invention includes a first pixel electrode, a first bank that is provided on the first pixel electrode and partitions between a first sub light emitting area and a first main light emitting area, a first sub hole injection layer that is provided on the first pixel electrode and constitutes the first sub light emitting area, a first main hole injection layer that is provided on the first pixel electrode and constitutes the first main light emitting area, a hole transport layer that is provided on the first sub hole injection layer and the first main hole injection layer, a first light emitting layer that is provided on the hole transport layer, an electron transport layer that is provided on the first light emitting layer; and a counter electrode that is provided on the electron transport layer, wherein a concentration of a dopant included in the first main hole injection layer is lower than a concentration of a dopant included in the first sub hole injection layer.

A method for manufacturing display device according to an aspect of the present invention includes steps of providing a first pixel electrode and a second pixel electrode adjacent to the first pixel electrode, providing a bank between the first pixel electrode and the second pixel electrode, providing a first sub hole injection layer and a first main hole injection layer on the first pixel electrode, a volume of the first main hole injection layer being larger than a volume of the first sub hole injection layer, and providing a second sub hole injection layer and a second main hole injection layer on the second pixel electrode, a volume of the second main hole injection layer being larger than a volume of the second sub hole injection layer, wherein the second main hole injection layer is provided after the first sub hole injection layer is provided and covers an end portion of the first sub hole injection layer on the bank.

### BRIEF DESCRIPTION OF THE DRAWINGS

FIG. 1 is a schematic diagram illustrating a configuration of a display device according to the present embodiment;

FIG. 2 is a schematic plan view of a display panel of the display device according to the present embodiment;

FIG. 3 is an enlarged partial sectional view of a light emitting unit and its periphery;

FIG. 4 is a cross-sectional view of the display panel taken along a line IV-IV shown in FIGS. 2 and 5;

FIG. 5 is a schematic plan view of an arrangement of light emitting areas of the present embodiment;

FIG. 6 is a schematic plan view of an arrangement of the light emitting areas in the first modification;

FIG. 7 is a schematic plan view of an arrangement of the light emitting areas in the second modification; and

FIG. 8 is a schematic plan view of an arrangement of the light emitting areas in the third modification.

### DETAILED DESCRIPTION OF THE INVENTION

An embodiment of the present invention (hereinafter, present embodiment) will be described below in detail with reference to the accompanying drawings. The disclosure is merely an example, and appropriate modifications while keeping the gist of the invention that can be easily conceived by those skilled in the art are naturally included in the scope of the invention. The accompanying drawings may schematically illustrate widths, thicknesses, shapes, or other characteristics of each part for clarity of illustration, compared to actual configurations. However, such a schematic illustration is merely an example and not intended to limit the present invention. In this specification and each drawing, the same elements as those already described with reference to the already-presented drawings are denoted by the same reference numerals, and detailed description thereof may be appropriately omitted.

Further, in the present specification, when a positional relationship between a component and another component is defined, if not otherwise stated, the words “on” and “below” suggest not only a case where the another component is disposed immediately on or below the component, but also a case where the component is disposed on or below the another component with a third component interposed therebetween.

### [Outline of Overall Configuration]

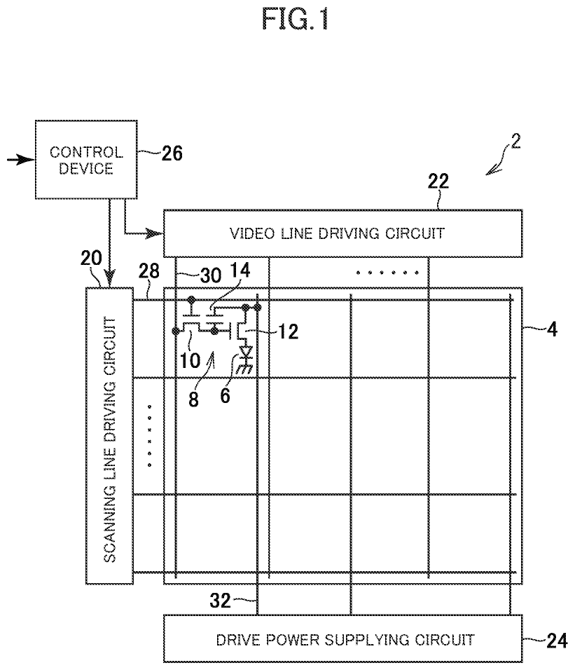

FIG. 1 is a schematic diagram illustrating a configuration of a display device according to the present embodiment. A display device 2 according to the present embodiment is an organic EL display device having a substrate on which a laminate structure of, for example, a thin film transistor (TFT) and an organic light emitting diode (OLED) is formed. The display device 2 includes a pixel array unit 4 for displaying images and a driving unit for driving the pixel array unit 4.

Pixels each having an OLED 6 and a pixel circuit 8 are arranged in a matrix in the pixel array unit 4. The pixel circuit 8 includes a plurality of TFTs 10 and 12 and capacitors 14.

The driving unit includes a scanning line driving circuit 20, a video line driving circuit 22, a drive power supplying circuit 24, and a control device 26, and drives the pixel circuit 8 to control light emission of the OLED 6.

The scanning line driving circuit 20 is connected to a scanning signal line 28 provided for each horizontal pixel array (pixel row). The scanning line driving circuit 20 sequentially selects the scanning signal lines 28 in response to a timing signal entered from the control device 26, and applies a voltage to the selected scanning signal line 28 to turn on a switching TFT 10.

The video line driving circuit 22 is connected to a video signal line 30 provided for each vertical pixel array (pixel column). The video line driving circuit 22 receives a video signal from the control device 26, and, in accordance with the selection of the scanning signal line 28 by the scanning line driving circuit 20, outputs a voltage corresponding to the video signal in the selected pixel row to each video signal line 30. The voltage is written to the capacitor 14 via the switching TFT 10 at the selected pixel row. The drive TFT12 supplies a current corresponding to the written voltage to the OLED 6. This causes the OLED 6 of the pixel corresponding to the selected scanning signal line 28 to emit light.

The drive power supplying circuit 24 is connected to a drive power supply line 32 provided for each pixel column, and supplies a current to the OLED 6 via the drive power supply line 32 and the drive TFT 12 in the selected pixel row. The drive power supply line 32 is provided for each pixel column in FIG. 1, but may be provided for each pixel row, or may be provided for both of them.

The OLED 6 includes a pixel electrode 46 and a common electrode 50 to be described later. The pixel electrode 46 of the OLED 6 is connected to the drive TFT12. The common electrode 50 of the OLEDs 6 is constituted by an electrode common to the OLEDs 6 of all the pixels. In a case where the pixel electrode 46 is configured as an anode, a high potential is input, and the common electrode 50 is configured as a cathode and a low potential is input. In a case where the pixel electrode 46 is configured as a cathode, a low potential is input, and the common electrode 50 is configured as an anode and a high potential is input.

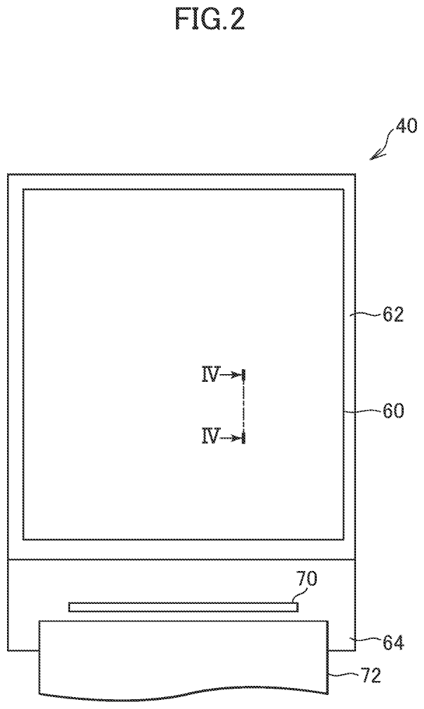

FIG. 2 is a schematic plan view of a display panel of the display device according to the present embodiment. The pixel array unit 4 shown in FIG. 1 is provided in the display area 60 of the display panel 40. As described above, a hole injecting layer 80 and the OLEDs 6 (light emitting units 100) are arranged in the pixel array unit 4. The common electrode 50 is formed in common to the pixels and covers the entire display area 60. A frame area 62 is provided around the display area 60, and the scanning line driving circuit 20, the video line driving circuit 22, and the drive power supplying circuit 24, and the control device 26 are provided, for example.

A terminal area 64 is provided on one side of the frame area 62 of the rectangular display panel 40. Wiring connected to the display area 60 is arranged in the terminal area 64. Further, the terminal area 64 also includes a driver IC 70 constituting the driving unit, and a flexible printed circuit board (FPC) 72 connected thereto. The FPC 72 may be connected to the control device 26 or other circuits 20, 22, and 24, for example, or may include an IC mounted thereon.

### [Outline of Laminated Structure of Display Area]

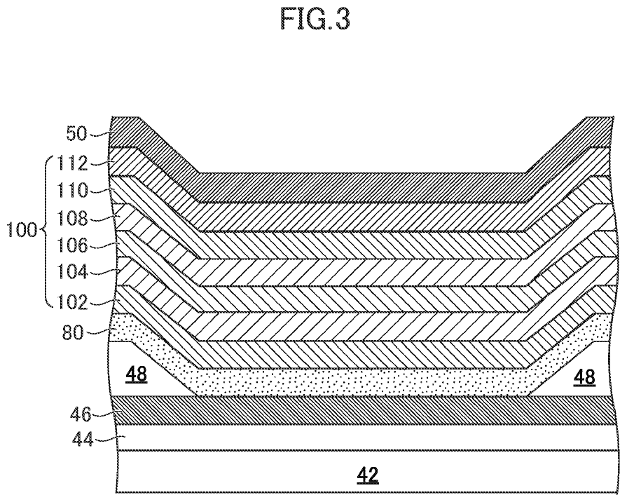

FIG. 3 is an enlarged partial sectional view of a light emitting unit and its periphery. The thickness of each layer in FIG. 3 does not reflect the actual thickness. Further, other layers (not shown) may be further provided in the light emitting unit 100 and the periphery thereof.

As shown in FIG. 3, in the present embodiment, a light emitting element is constituted by a light emitting unit 100, a hole injection layer 80, and a pixel electrode 46 and the common electrode 50 with the light emitting unit 100 and the hole injection layer 80 therebetween. A light emitting layer 106 included in the light emitting unit 100 is formed of an organic material, and emits light by a current flowing between the pixel electrode 46 and the common electrode 50. In the example shown in FIG. 3, the pixel electrode 46 is provided on a passivation film 44 on the TFT substrate 42.

The light emitting unit 100 is disposed between the pixel electrode 46 and the common electrode 50. The light emitting unit 100 is a lamination of a hole transport layer 102, an electron block layer 104, a light emitting layer 106, a hole block layer 108, an electron transport layer 110, and an electron injection layer 112, which are laminated on the pixel electrode 46 in this order. The hole transport layer 102 is formed on the hole injection layer 80 in contact with the pixel electrode 46. In the present embodiment, the light emitting unit 100 and the hole injection layer 80 are described separately, although the hole injection layer 80 may be a part of the light emitting unit 100.

The common electrode 50 is formed as a uniform film (a so-called solid film) extending throughout the display area 60. The common electrode 50 is formed of a metallic thin film, such as MgAg. In a case where a metal thin film is used for the display device 2 employing a top emission structure, the film thickness needs to be reduced to such an extent that light is transmitted therethrough. In a case where the display device 2 employs a bottom emission structure, the common electrode 50 needs to be formed as a reflective electrode. The top emission structure is employed in this case, and thus the common electrode 50 is formed of MgAg as a thin film through which light emitted from the light emitting layer 106 passes. According to the example of the order of forming the light emitting unit 100, the pixel electrode 46 serves as an anode, and the common electrode 50 serves as a cathode.

The display panel 40 of the display device 2 includes a bank 48 (also referred to as a rib), which is a partition wall that partitions the pixels. The bank 48 is an insulating layer that separates pixel electrodes 46 adjacent to each other. The bank 48 is formed of a photosensitive resin, such as photosensitive acrylic. The end portion of the bank 48 preferably has a smoothly tapered shape. As will be described later, in the present embodiment, the bank 48 is also provided so as to partition between a main light emitting area and a sub light emitting area in one pixel.

If a TFT of the TFT substrate 42 is a driving TFT having n channels, the pixel electrode 46 is connected to the source electrode of the TFT. The pixel electrode 46 may be formed of a transparent metallic oxide, such as ITO and IZO. Alternatively, a metallic material such as Ag and Al may be formed as a thin film to provide a pixel electrode 46. The TFT substrate 42 may include a base material, an undercoat layer, a TFT, a conductive layer, a gate electrode, a source-drain electrode, and a flattening film, for example. These elements are similar to the conventional configuration, and thus detailed description thereof will be omitted.

The display panel 40 may further include a sealing layer that seals the light emitting unit 100 and a protective layer that is provided on the sealing layer. The sealing layer may have a sealing function of preventing moisture intrusion from the outside.

### [Configuration to Inhibit Mixture of Light Colors]

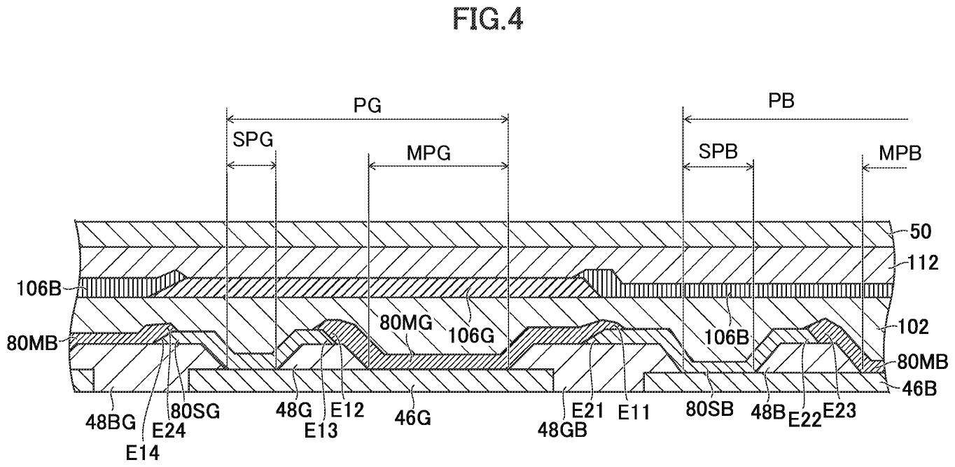

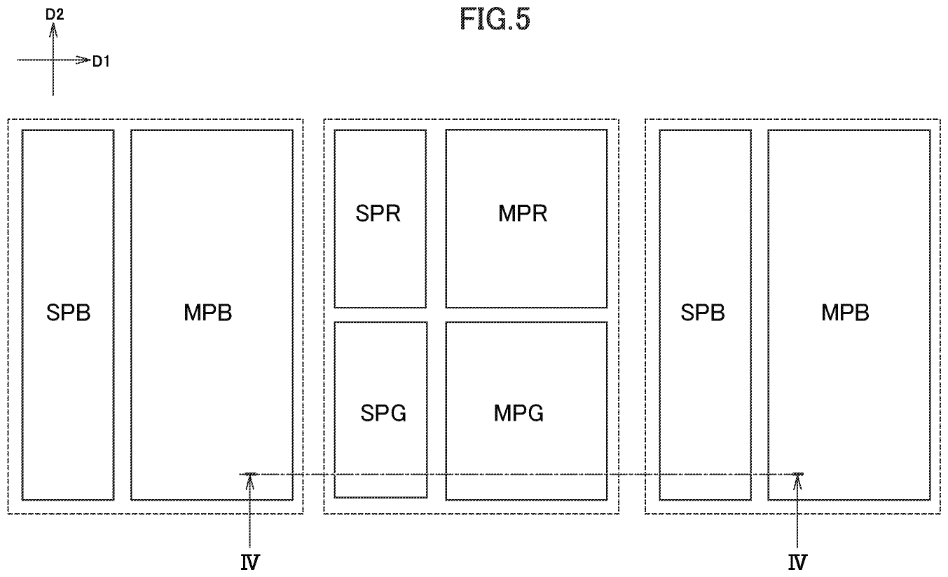

FIG. 4 is a cross-sectional view of the display panel 40 taken along the line IV-IV shown in FIGS. 2 and 5. FIG. 5 is a schematic plan view of the arrangement of the light emitting areas of the present embodiment. In FIG. 4, a part of the layer included in the light emitting unit 100 is omitted.

In general, a driving voltage as a light emission start voltage in a blue pixel is higher than a driving voltage as a light emission start voltage in a green pixel and a red pixel. As such, when a blue pixel emits light, holes in the hole injection layer leak into adjacent green pixels or red pixels, so that light emission in green pixels or red pixels may occur unintentionally. This may cause mixture of light colors.

In the present embodiment, in order to prevent adjacent pixels from unintentionally emitting light when the blue pixel emits light, a main light emitting area and a sub light emitting area are provided in each pixel and a driving voltage in the main light emitting area is higher than a driving voltage in the sub light emitting area. In the present embodiment, a light emitting area of the main light emitting area is larger in size than a light emitting area of the sub light emitting area. The light emitting area is an area where light is emitted in a plan view.

FIGS. 4 and 5 show an example in which a blue pixel PB, a green pixel PG (and a red pixel PR), and a blue pixel PB are disposed in this order. In the present embodiment, a light emitting layer 106 is provided so as to correspond to each pixel. Specifically, a green light emitting layer 106G is provided so as to correspond to the green pixel PG, and a blue light emitting layer 106B is provided so as to correspond to the blue pixel PB.

In the present embodiment, the hole injection layer includes a sub hole injection layer and a main hole injection layer in each pixel. Specifically, as shown in FIG. 4, the green pixel PG includes a sub hole injection layer 80SG and a main hole injection layer 80MG, and the blue pixel PB includes a sub hole injection layer 80SB and a main hole injection layer 80MB.

In each pixel, a main hole injection layer and a sub hole injection layer are in contact with the common pixel electrode 46. In the present embodiment, an area where the sub hole injecting layer 80SG and the pixel electrode 46G are in contact with each other in a plan view is referred to as a sub light emitting area SPG. An area where the main hole injection layer 80MG and the pixel electrode 46G are in contact with each other in a plan view is referred to as a main light emitting area MPG. Similarly, an area where the sub hole injecting layer 80SB and the pixel electrode 46B are in contact with each other in a plan view is referred to as a sub light emitting area SPB. An area where the main hole injection layer 80MB and the pixel electrode 46B are in contact with each other in a plan view is referred to as a main light emitting area MPB.

In each pixel, a bank 48 partitions between the main light emitting area and the sub light emitting area. For example, as shown in FIG. 4, a bank 48G partitions between the main light emitting area MPG and the sub light emitting area SPG in the green pixel PG.

As shown in FIG. 4, the main hole injection layer 80MG includes an end portion E11 and an end portion E12, and the sub hole injection layer 80SG includes an end portion E13 and an end portion E14. The main hole injection layer 80MB includes end portions E23 and E24, and the sub hole injection layer 80SB includes end portions E21 and E22. As shown in FIG. 4, the end portion E11 of the main hole injection layer 80MG is in contact with the end portion E21 of the sub hole injection layer 80SB, and the end portion E12 of the main hole injection layer 80MG is in contact with the end portion E13 of the sub hole injection layer 80SG. The end portion E14 of the sub hole injection layer 80SG is in contact with the end portion E24 of the main hole injection layer 80MB. The end portion E22 of the sub hole injection layer 80SB is in contact with the end portion E23 of the main hole injection layer 80MB.

### [Configuration to Inhibit Mixture of Light Colors: Inhibiting Mixture of Colors During Light Emission of Blue Pixel in Sub Light Emitting Area]

In the present embodiment, the driving voltage of the main light emitting area MPG in the green pixel PG is relatively high, and thus unintended light emission is inhibited even if a leakage occurs. Specifically, the concentration of the dopant contained in the main hole injection layer 80MG is lower than the concentration of the dopant contained in the sub hole injection layer 80SG. the dopant serves to stimulate generation of holes by charge separation in the hole injection layer 80. As such, the driving voltage is relatively low in the sub light emitting area SPG in which the concentration of the dopant is relatively high, and the driving voltage is relatively high in the main light emitting area MPG in which the concentration of the dopant is relatively low. Examples of doped materials constituting the dopant include, but are not limited to, molybdenum oxide (MoO3), rhenium oxide (Re207), and fluorinated tetracyanoquinodimethane (F4-TCNQ).

In each pixel, the concentration of the dopant in the main hole injection layer may be one-tenth or less of the concentration of the dopant in the sub hole injection layer. For example, the concentration of the dopant in the sub hole injection layer may be 20 to 30%. The concentration of the dopant in the main hole injection layer may be 2 to 3%. The concentration of the dopant in the sub hole injection layer may be 20% or less, and the concentration of the dopant in the main hole injection layer may be 2% or less.

In each pixel, the total amount of dopants in the main hole injection layer may be larger than the total amount of dopants in the sub hole injection layer. As such, the volume of the main hole injection layer may be larger than the volume of the sub hole injection layer. For example, in a case where the concentration of the dopant in the main hole injection layer is one-tenth of the concentration of the dopant in the sub hole injection layer, the volume of the main hole injection layer may be larger than 10 times the volume of the sub hole injection layer. The average thickness of the main hole injection layer may be larger than the average thickness of the sub hole injection layer.

In the present embodiment, when a voltage equal to or higher than the driving voltage of the sub light emitting area and lower than the driving voltage of the main light emitting area is applied to each pixel, only the sub light emitting area emits light. When the voltage is increased from such a state to be equal to or higher than the driving voltage of the main light emitting area and applied, the light emission stops in the sub light emitting area and starts in the main light emitting area. This is because a current flows predominantly in the main light emitting area in which the total amount of dopants is large in the high voltage band.

As described above, in the present embodiment, the driving voltage is set to be relatively high in the main light emitting area MPG, and thus, when the blue pixel PB emits light, it is possible to prevent the sub light emitting area SPG in the green pixel PG from unintentionally emitting light even if the hole leaks to the end portion E11 of the main hole injection layer 80MG through the end portion E21 of the sub hole injection layer 80SB. This serves to prevent mixture of light colors. Further, low-voltage driving is available in the sub light emitting area, and the power consumption can be thereby reduced as compared with a configuration in which the voltage of the entire light emitting area is high.

In the present embodiment, each pixel includes a main light emitting area and a sub light emitting area, and the dopant concentration of the main hole injection layer in the main light emitting area is lower than the dopant concentration of the sub hole injection layer in the sub light emitting area. However, the present invention is not limited thereto, and at least the red pixel PR or the green pixel PG may employ such a configuration. For example, the blue pixel PB may not include the main light emitting area and the sub light emitting area but include only one type of light emitting area.

In the present embodiment, the light emitting layer 106 is provided in common between the sub light emitting area and the main light emitting area, but the present invention is not limited thereto and the light emitting layer 106 may be separately coated between the sub light emitting area and the main light emitting area.

### [Configuration to Inhibit Mixture of Light Colors: Inhibiting Mixture of Colors During Light Emission of Blue Pixel in Main Light Emitting Area]

The present embodiment employs the configuration to prevent the sub light emitting area SPG from unintentionally emitting light due to a leakage from the main hole injection layer 80MB to the sub hole injection layer 80SG when the main light emitting area MPB in the blue pixel PB emits light.

Specifically, the end portion E24 of the main hole injection layer 80MB is formed so as to cover the end portion E14 of the sub hole injection layer 80SG. The holes generated in the hole injection layer 80 move toward the light emitting layer 106 in the display device 2. As such, the holes move from the end portion on the lower layer side to the end portion on the upper layer side in a portion of the end portions of the hole injection layer 80 that are in contact with each other. In the present embodiment, the end portion E24 covers the end portion E14, and thus the holes easily move from the end portion E14 to the end portion E24, and hardly move from the end portion E24 to the end portion E14. Accordingly, when the main light emitting area MPB emits light, a leakage from the end portion E24 of the main hole injection layer 80MB to the end portion E14 of the sub hole injection layer SG is unlikely to occur, and this prevents the sub light emitting area SPG from unintentionally emitting light. In the present embodiment, when the sub light emitting area SPG emits light, the main light emitting area MPB is less likely to emit light unintentionally even if a leakage occurs, because the driving voltage is high.

### [Manufacturing Method]

Next, a method of manufacturing the display device 2 according to the present embodiment will be described.

First, a passivation film 44 is formed on the TFT substrate 42, and a plurality of pixel electrodes 46 are formed on the passivation film 44. Next, a bank 48 is provided so as to partition pixel electrodes 46 adjacent to each other and also extend over such pixel electrodes 46. FIG. 4 shows an example in which a bank 48GB is provided so as to partition between the pixel electrode 46G in the green pixel PG and the pixel electrode 46B in the blue pixel PB. Further, a bank 48BG is provided so as to partition between the pixel electrode 46B in the blue pixel PB and the pixel electrode 46G in the green pixel PG.

In each pixel, a bank 48 is provided for partitioning between a main light emitting area and a sub light emitting area. FIG. 4 shows an example in which the bank 48G is provided on the pixel electrodes 46G in the green pixel PG so as to partition between the main light emitting area MPG and the sub light emitting area SPG. Further, a bank 48B is provided on the pixel electrode 46B in the blue pixel PB to partition between the main light emitting area MPB and the sub light emitting area SPB.

A hole injection layer 80 is then provided on the bank 48 and the pixel electrode 46. In the present embodiment, a sub hole injection layer is provided, and then a main injection layer is provided so as to cover an end portion of the sub hole injection layer.

Specifically, the sub hole injection layer 80SG is provided on the pixel electrode 46G so as to extend over the bank 48BG and the bank 48G. The sub hole injection layer 80SB is provided on the pixel electrode 46 so as to extend over the bank 48GB and the bank 48B.

The main hole injection layer 80MG is provided so as to cover the end portion E13 of the sub hole injection layer 80SG and the end portion E21 of the sub hole injection layer 80SB. Further, the main hole injection layer 80MB is provided so as to cover the end portion E14 of the sub hole injection layer 80SG and the end portion E22 of the sub hole injection layer SB. In the following, layers included in the light emitting unit 100 may be laminated although detailed description is omitted.

### First Modification

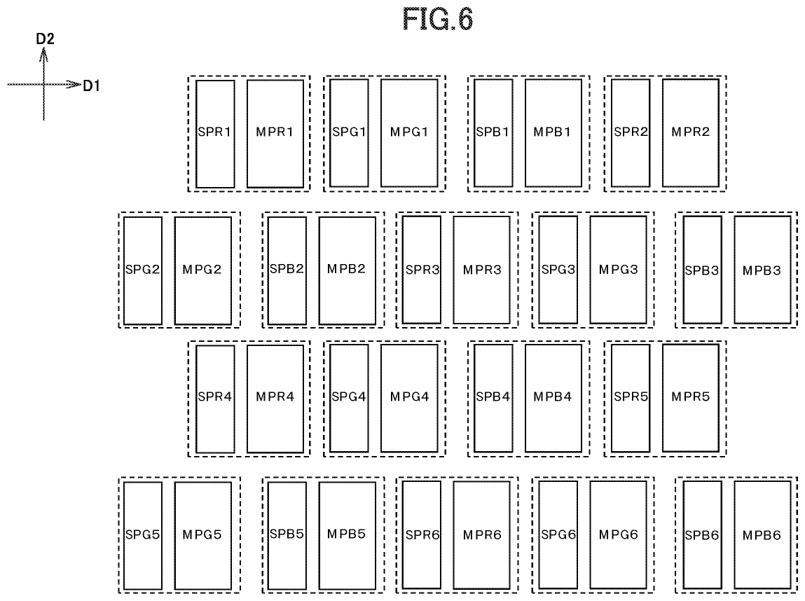

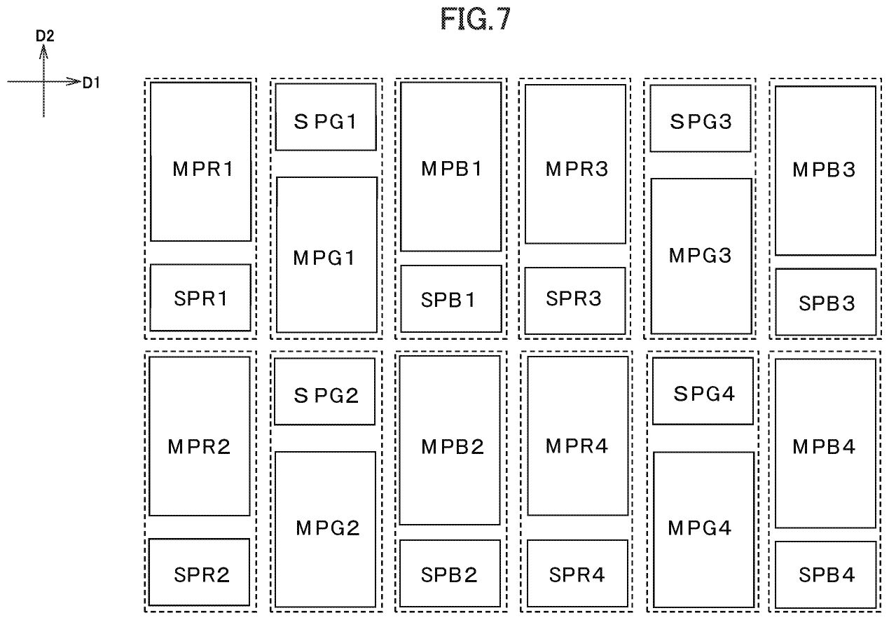

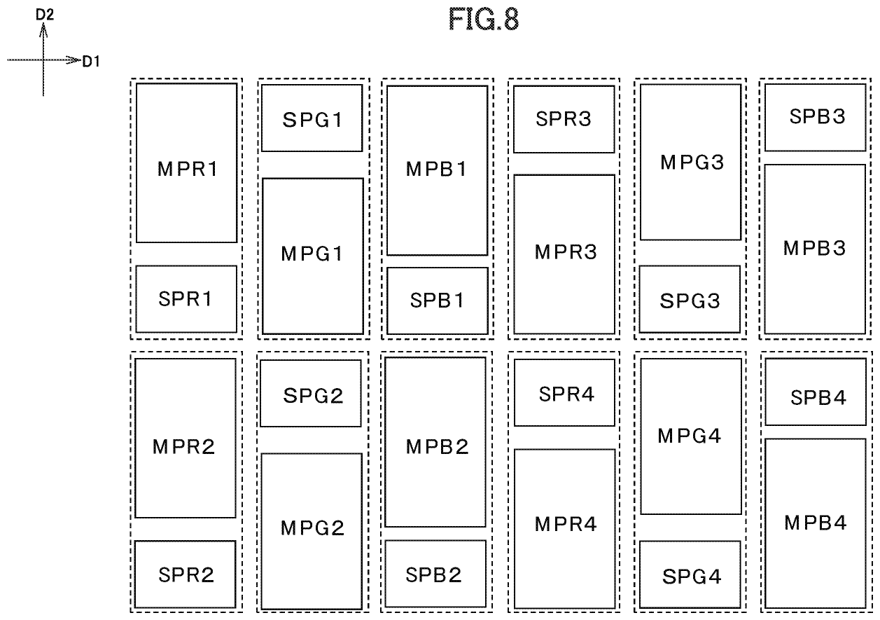

Next, referring to FIG. 6, a modification of the arrangement of the light emitting areas will be described. FIG. 6 is a schematic plan view of the light emitting areas arranged in the first modification. FIG. 6 shows a plurality of light emitting areas arranged in a first direction D1 and a second direction D2. The rectangle broken line in FIG. 6 indicates one pixel. That is, one pixel includes a main light emitting area and a sub light emitting area. The same applies to FIGS. 7 and 8 described later.

In the first modification, as in the embodiment described above, each pixel includes a main light emitting area and a sub light emitting area, and the dopant concentration of the main hole injection layer in the main light emitting area is lower than the dopant concentration of the sub hole injection layer in the sub light emitting area. That is, the driving voltage is relatively high in the main light emitting area. The overall configuration of the display device and the laminate structure of the light emitting unit 100 may be the same as those described in the present embodiment with reference to FIGS. 1 to 4.

In the example shown in FIG. 6, sub light emitting areas and main light emitting areas are arranged in the first direction D1 in each pixel. Further, green pixels, blue pixels, and red pixels are arranged in this order in the first direction D1. By virtue of such an arrangement, a main light emitting area in each pixel is adjacent to a sub light emitting area of the adjacent pixel in the first direction D1, and a sub light emitting area of each pixel is adjacent to a main light emitting area of the adjacent pixel in the first direction D1.

In the example shown in FIG. 6, a main light emitting area in each pixel is adjacent to a sub light emitting area of the adjacent pixel in the second direction D2, and a sub light emitting area of each pixel is adjacent to a main light emitting area of the adjacent pixel in the second direction D2.

As described above, in the first modification, the main light emitting areas of the respective pixels are adjacent to the sub light emitting areas of the adjacent pixels in the first direction D1 and the second direction D2. Accordingly, if a hole leaks when the sub light emitting area in the adjacent pixel emits light, it is possible to prevent the main light emitting area from unintentionally emitting light. This serves to prevent mixture of light colors.

### Second Modification

FIG. 7 is a schematic plan view of the light emitting areas arranged in the second modification.

In the second modification, sub light emitting areas and main light emitting areas are arranged in the second direction D2 in each pixel. In the second modification, the pixels of the same color have the same relative positions of the sub light emitting area and the main light emitting area. Specifically, for example, in the blue pixel, the relative positions of the sub light emitting area SPB1 and the main light emitting area MPB1 are the same as the relative positions of the sub light emitting area SPB2 and the main light emitting area MPB2.

In at least some of the pixels adjacent in the first direction D1, the sub light emitting areas and the main light emitting areas are provided on opposite sides in the second direction. For example, the main light emitting area MPR1 is adjacent to the sub light emitting area SPG1 in the first direction, and the sub light emitting area SPRI is adjacent to the main light emitting area MPG1 in the first direction. By virtue of such an arrangement, if a hole leaks when the sub light emitting area in the adjacent pixel emits light, it is possible to prevent the main light emitting area from unintentionally emitting light. This serves to prevent mixture of light colors.

### Third Modification

FIG. 8 is a schematic plan view of the light emitting areas arranged in the third modification.

In the second modification described with reference to FIG. 7, the pixels of the same color have the same relative positions of the sub light emitting area and the main light emitting area. In the third modification, the positions of the sub light emitting areas and the main light emitting areas in the pixels of the same color closest in the first direction are reversed. Specifically, the main light emitting area MPB1 and the main light emitting area MPB2 are positioned opposite to each other in the second direction D2, and the sub light emitting area SPB1 and the sub light emitting area SPB2 are positioned opposite to each other in the second direction D2. Such an arrangement serves to increase the number of main light emitting areas and sub light emitting areas that are adjacent to each other. Accordingly, if a hole leaks when the sub light emitting area in the adjacent pixel emits light, it is possible to prevent the main light emitting area from unintentionally emitting light. This serves to prevent mixture of light colors.

What is claimed is:

1. A display device comprising:
a first pixel electrode;
a first bank that is provided on the first pixel electrode and partitions between a first sub light emitting area and a first main light emitting area;
a first sub hole injection layer that is provided on the first pixel electrode in the first sub light emitting area;
a first main hole injection layer that is provided on the first pixel electrode in the first main light emitting area;
a hole transport layer that is provided on the first sub hole injection layer and the first main hole injection layer;
a first light emitting layer that is provided on the hole transport layer;
an electron transport layer that is provided on the first light emitting layer; and
a counter electrode that is provided on the electron transport layer, wherein
a concentration of a dopant included in the first main hole injection layer is lower than a concentration of a dopant included in the first sub hole injection layer.

2. The display device according to claim 1, wherein
a total amount of dopant included in the first main hole injection layer is larger than a total amount of dopant included in the first sub hole injection layer.

3. The display device according to claim 2, wherein
a volume of the first main hole injection layer is larger than a volume of the first sub hole injection layer.

4. The display device according to claim 2, wherein
a light emitting area of the first main light emitting area is larger than a light emitting area of the first sub light emitting area.

5. The display device according to claim 2, wherein
an average thickness of the first main hole injection layer is thicker than an average thickness of the first sub hole injection layer.

6. The display device according to claim 2, wherein
a light emission start voltage in the first main light emitting area is higher than a light emission start voltage in the first sub light emitting area.

7. The display device according to claim 1, further comprising:
a second pixel electrode adjacent to the first pixel electrode;
a second bank that is provided on the second pixel electrode and partitions between a second sub light emitting area and a second main light emitting area;
a second sub hole injection layer that is provided on the second pixel electrode in the second sub light emitting area;
a second main hole injection layer that is provided on the second pixel electrode in the second main light emitting area; and
a second light emitting layer that is provided on the hole transport layer, wherein
the hole transport layer is provided on the second sub hole injection layer and the second main hole injection layer,
the electron transport layer is provided on the second light emitting layer, and
an end portion of the second main hole injection layer is provided so as to cover an end portion of the first sub hole injection layer.

8. The display device according to claim 7, further comprising:
a third pixel electrode adjacent to the first pixel electrode;
a third bank that is provided on the third pixel electrode and partitions between a third sub light emitting area and a third main light emitting area;
a third sub hole injection layer that is provided on the third pixel electrode in the third sub light emitting area;
a third main hole injection layer that is provided on the third pixel electrode in the third main light emitting area; and
a third light emitting layer that is provided on the hole transport layer, wherein
the hole transport layer is provided on the third sub hole injection layer and the third main hole injection layer,
the electron transport layer is provided on the third light emitting layer,
the first main light emitting area and the third sub light emitting area are disposed so as to be adjacent to each other, and
the first sub light emitting area and the second main light emitting area are disposed so as to be adjacent to each other.

9. The display device according to claim 7, wherein
the first main light emitting area and the first sub light emitting area are a part of a red pixel or a green pixel, and
the second main light emitting area and the second sub light emitting area are a part of a blue pixel.

10. The display device according to claim 1, further comprising an electron injection layer between the electron transport layer and the counter electrode.

11. A method for manufacturing display device, the method comprising the steps of:
providing a first pixel electrode and a second pixel electrode adjacent to the first pixel electrode;
providing a bank between the first pixel electrode and the second pixel electrode;
providing a first sub hole injection layer and a first main hole injection layer on the first pixel electrode, a volume of the first main hole injection layer being larger than a volume of the first sub hole injection layer; and
providing a second sub hole injection layer and a second main hole injection layer on the second pixel electrode, a volume of the second main hole injection layer being larger than a volume of the second sub hole injection layer, wherein
the second main hole injection layer is provided after the first sub hole injection layer is provided and covers an end portion of the first sub hole injection layer on the bank.
